(19) United States
(12) Patent Application Publication
(10) Pub. No.: US 2014/0009039 A1
(43) Pub. Date: Jan. 9, 2014

(54) POLYMER LAYER COMPOSITE WITH FERROELECTRET PROPERTIES AND METHOD FOR PRODUCING SAID COMPOSITE

(71) Applicants: Werner Jenninger, Koln (DE); Deliani Lovera-Prieto, Bundde (NL)

(72) Inventors: Werner Jenninger, Koln (DE); Deliani Lovera-Prieto, Bundde (NL)

(73) Assignee: BAYER INTELLECTUAL PROPERTY GMBH, Monheim (DE)

(21) Appl. No.: 13/883,286

(22) PCT Filed: Oct. 28, 2011
(86) PCT No.: PCT/EP11/69043

§ 371 Date: Sep. 24, 2013

(30) Foreign Application Priority Data
Nov. 3, 2010 (EP) 10189897.1

(51) Int. Cl. H01L 41/08; H01L 41/333; H01L 41/193

(52) U.S. Cl. CPC H01L 41/08; H01L 41/193; H01L 41/333
USPC 310/367; 428/309.9; 264/413; 264/423

(57) ABSTRACT

The present invention relates to a polymer layer structure with ferroelectret properties, comprising a continuous first polymer layer (1) and a continuous second polymer layer (2), the first and second polymer layers (1, 2) being connected to one another to form voids (4) by connecting portions (3) arranged between the continuous polymer layers (1, 2). According to the invention, the polymer layer structure is in the form of an integral extruded structural element.

The present invention relates to a polymer layer structure with ferroelectret properties, having a first continuous polymer layer and a second continuous polymer layer, the first and second polymer layers being connected to one another to form voids by connecting portions which are arranged at an angle relative to the continuous polymer layers. The present invention relates further to a process for the production of a polymer layer composite according to the invention, and to a piezoelectric element comprising a polymer layer composite according to the invention.

Because of their advantageous and purposively adjustable properties, such as, for example, low weight, thermal conductivity, mechanical deformability, electrical properties and barrier functions, polymers and polymer composite materials are used in a large number of commercial applications. They are used, for example, as packaging material for foodstuffs or other products, as construction or insulating materials, for example in the building industry or in motor vehicle construction. However, functional polymers are also becoming increasingly important as active components in sensor or actuator applications.

An important application concept concerns the use of the polymers as electromechanical or piezoelectric converters. Piezoelectric materials are capable of converting a mechanical pressure into an electrical voltage signal. Conversely, an electrical field applied to the piezoelectric material can be transformed into a change in the converter geometry. Piezoelectric materials are already included as active components in a large number of applications. These include, for example, structured pressure sensors for keyboards or touch pads, acceleration sensors, microphones, loudspeakers, ultrasound converters for applications in medical technology, marine technology or for materials testing. For example, in patent application WO 2006/053528 A1 an electroacoustic transducer based on a piezoelectric element of polymer films is described.

In recent years, a new class of piezoelectric polymers, the so-called ferroelectrets, has increasingly been the focus of research. Ferroelectrets are also called piezoelectrets. Ferroelectrets are polymer materials with a void structure which are able to store electric charges over long periods. The ferroelectrets known hitherto exhibit a cellular void structure and are in the form of either foamed polymer films or multilayer systems of polymer films or polymer fabrics. If electric charges are distributed over the different surfaces of the voids according to their polarity, each charged void represents an electric dipole. If the voids are then deformed, this causes a change in the dipole size and leads to a current flow between external electrodes. The ferroelectrets can exhibit a piezoelectric activity which is comparable to that of other piezoelectric materials.

Ferroelectrets continue to be of increasing interest for commercial applications, for example for sensor, actuator and generator systems. In terms of economy, it is essential that a production process should be usable on an industrial scale.

A process for the production of foamed ferroelectret polymer films is the direct physical foaming of a homogeneous film with supercritical liquids, for example with carbon dioxide. This process has been described in the publication Advanced Functional Materials 17, 324-329 (2007), Werner Wirges, Michael Wegener, Olena Voronina, Larissa Zirkel and Reimund Gerhard-Multhaupt “Optimized preparation of elastically soft, highly piezoelectric, cellular ferroelectrets from nonvoided poly(ethylene terephthalate) films” and in Applied Physics Letters 90, 192908 (2007), P. Fang, M. Wegener, W. Wirges and R. Gerhard L. Zirkel “Cellular polyethylene-naphthalate ferroelectrets: Foaming in supercritical carbon dioxide, structural and electrical preparation, and resulting piezoelectricity” with polyester materials and in Applied Physics A: Materials Science & Processing 90, 615-618 (2008), O. Voronina, M. Wegener, W. Wirges, R. Gerhard, L. Zirkel and H. Münstedt “Physical foaming of fluorinated ethylene-propylene (FEP) copolymers in supercritical carbon dioxide: single film fluoropolymer piezoelectrets” for a fluoropolymer FEP (fluorinated ethylene-propylene copolymer).

However, the foamed polymer films have the disadvantage that a wide bubble size distribution can occur. As a result, all the bubbles may not be charged equally well in the subsequent charging step.

In the case of ferroelectret multilayer systems there are known inter alia arrangements of hard and soft layers with charges introduced between them. In “Double-layer electret transducer”, Journal of Electrostatics, Vol. 39, pp. 33-40, 1997, R. Kacprzyk, A. Dobrucki and J. B. Gajewski, multiple layers of solid materials having very different moduli of elasticity are described. However, they have the disadvantage that such layer systems exhibit only a relatively slight piezoelectric effect.

The newest developments in the field of ferroelectrets provide structured polymer layers. Multilayer systems comprising closed outer layers and a porous or perforated middle layer are described in several publications from recent years. These include the articles by Z. Hu and H. von Seggern, “Air-breakdown charging mechanism of fibrous polytetrafluoroethylene films”, Journal of Applied Physics, Vol. 98, paper 014108, 2005 and “Breakdown-induced polarization buildup in porous fluoropolymer sandwiches: A thermally stable piezoelectret”, Journal of Applied Physics, Vol. 99, paper 024102, 2006, as well as the publication by H. C. Basso, R. A. P. Altafilm, R. A. C. Altafilm, A. Mellinger, Peng Fang, W. Wirges and R. Gerhard “Three-layer ferroelectrets from perforated Teflon-PTFE films fused between two homogeneous Teflon-FEP films” IEEE, 2007 Annual Report Conference on Electrical Insulation and Dielectric Phenomena, 1-4244-1482-2/07, 453-456 (2007) and the article by Jinfeng Huang, Xiaoqing Zhang, Zhongfu Xia and Xuewen Wang “Piezoelectrets from laminated sandwiches of porous polytetrafluoroethylene films and nonporous fluoroethylenepropylene films”, Journal of Applied Physics, Vol. 103, paper 084111, 2008.

Layer systems having a porous or perforated middle layer frequently have higher piezoelectric constants compared with the systems described above. However, it is not always possible to reliably laminate the middle layers with the solid outer layers. Moreover, perforation of the middle layer is generally very expensive in terms of time.

A production method for ferroelectrets having tubular voids of homogeneous size and structure has been described by R. A. P. Altafim, X. Qiu, W. Wirges, R. Gerhard, R. A. C. Altafim, H. C. Basso, W. Jenninger and J. Wagner in the article “Template-based fluoroethylenepropylene piezoelectrets with tubular channels for transducer applications”, Journal of Applied Physics 106, 014106 (2009). In the process described therein, a sandwich arrangement of two FEP films and an intermediate PTFE masking film is first prepared. The resulting stack of films is laminated, the FEP films are bonded together and then the masking film is removed to free the voids.

Finally, WO 2010/066348 A2 discloses a process for the production of two- or multi-layer ferroelectrets having defined voids by structuring at least a first surface of a first polymer film to form a vertical profile, applying at least a second polymer film to the structured surface of the first polymer film formed in a first step, bonding the polymer films to form a polymer film composite with the formation of voids, and electrically charging the inner surfaces of the resulting voids with opposite electric charges. The patent application further provides ferroelectret multilayer composites, optionally produced by the processes according to the invention, comprising at least two polymer films which are arranged one above the other and are bonded together, voids being formed between the polymer films. In addition, the patent application relates to a piezoelectric element containing a ferroelectret multilayer composite according to the invention.

A common feature of all the above-described processes for the production of ferroelectrets is that, because the ferroelectrets to be produced are formed of a plurality of individual components, they are comparatively complex to carry out, which leads to high production costs.

Accordingly, the object underlying the invention is to provide a ferroelectret polymer layer structure and a process for the production of ferroelectrets with which defined ferroelectret void structures can be produced, wherein it is to be possible to carry out the process in particular simply and inexpensively even on a commercial and industrial scale.

The object is achieved according to the invention by a polymer layer composite according to claim 1 and a process according to claim 12. Advantageous further developments are described in the dependent claims.

The present invention accordingly relates to a polymer layer structure with ferroelectret properties. According to the invention, the polymer layer structure comprises a continuous first polymer layer and a continuous second polymer layer, the first and second polymer layers being connected to one another to form voids by connecting portions arranged between the continuous polymer layers. According to the invention, the polymer layer structure is characterised in that it is in the form of an integral extruded structural element.

An “integral extruded structural element” within the scope of the present invention is understood as meaning structural elements which acquire the structural form required for the particular intended use directly by the extrusion step without the necessity for further forming steps or joining steps, apart from any finishing necessary to ensure a consistently high product quality. In particular, an integral extruded structural element does not require individual components of the structural element to be connected following the extrusion.

Within the context of the present invention, ferroelectret properties means that, within voids, opposite electric charges are located on opposite surfaces of the void. As already stated, each void accordingly represents an electric dipole. When the void is deformed, a change in the dipole size occurs and an electric current is able to flow between appropriately connected external electrodes.

The particular advantage of the polymer layer structure according to the invention is that it can be produced in a highly efficient, inexpensive manner with a high degree of automation using an established production process, namely by means of extrusion. In the shaping of the polymer layer structure, in particular in the shaping of the desired void cross-sections, extrusion permits a high degree of freedom in terms of design. Accordingly, using an appropriate die shape, a plurality of cross-section geometries can be produced. It will be understood that, due to the process, the voids are formed in a tunnel-like manner with a constant cross-section over the entire extent of the extruded polymer layer structure, that is to say are in the form of parallel, linear, continuous channels.

The first and second polymer layers of the polymer layer structure can be formed with variable thickness, in particular with periodically varying thickness. According to a preferred embodiment of the invention, the thicknesses d1 and d2 of the first and second polymer layers are constant. The term “constant” is to be understood according to the invention as meaning that the thickness varies by not more than ±10% as a result of unavoidable fluctuations, fluctuations of not more than ±5% of the thickness being preferred.

The cross-sections of the voids can assume various geometric shapes. Round as well as polygonal cross-sections, especially tetragonal, in particular square, cross-sections, are conceivable.

According to an embodiment of the invention, at least some of the voids have a trapezoidal cross-section, in particular a symmetrical trapezoidal cross-section with legs of equal length. It is preferred for all the voids to have a trapezoidal, in particular symmetrically trapezoidal, cross-section, wherein in the case of a horizontally arranged polymer layer structure the longer base of a trapezium cross-section is arranged alternately above and below the associated shorter base. In other words: the trapezium cross-sections of adjacent voids can be transformed into one another by a point reflection. As a result, the connecting portions connecting the two continuous polymer layers can be formed with a thin wall thickness, because the legs of adjacent trapezium cross-sections can thus be oriented parallel to one another. This contributes towards the desired structural softness of the polymer layer structure. In addition, with a trapezoidal arrangement of the void cross-sections of the above-described type, adjacent connecting portions are arranged at an acute angle relative to one another and to the two polymer layers. This further contributes towards the desired structural softness, as a result of which the polymer layer structure exhibits inter alia a higher piezoelectric constant d₃₃ as compared with comparable ferroelectret systems with rectangular void cross-sections.

According to a further embodiment of the invention, in each trapezoidal cross-section each obtuse angle has two adjacent acute angles and each acute angle has two adjacent obtuse angles. This means that, in this specific trapezoidal cross-section, the connecting portions connecting the two continuous polymer layers are tilted in the same direction of rotation relative to the shortest connection between the two continuous polymer layers. The connecting portions are accordingly arranged “in the same direction”. It is particularly preferred thereby for the trapezoidal cross-section to have a parallelogram shape, the connecting portions having a uniform length and the continuous polymer layers being arranged parallel to one another. In the case of parallelogram-shaped cross-sections in particular, good structural softness is achieved.

According to a further embodiment of the invention, the thickness d1 of the first polymer layer is from ≧10 μm to ≦250 μm and the thickness d2 of the second polymer layer is from ≧10 μm to ≦250 μm. It is further preferred for the width a, defined as the length of the longer base of a trapezium cross-section, to be from ≧10 μm to ≦5 mm, preferably from ≧100 μm to ≦3 mm. The width b, defined as the width of the trapezium cross-section at half height, is preferably from ≧10 μm to ≦5 mm, preferably from ≧100 μm to ≦3 mm. The height h of the trapezium cross-section is preferably from ≧10 μm to ≦500 μm. The angle α enclosed between the longer base of the trapezium cross-section and a leg is preferably from ≧5° to ≦80°.

The parameter ranges indicated above permit optimum ferroelectret properties and can be achieved by appropriately configuring the extrusion system, especially the extrusion die.

According to a further embodiment of the invention, the polymer layer structure comprises a material which is selected from the group comprising polycarbonate, perfluorinated or partially fluorinated polymers and copolymers, polytetrafluoroethylene, fluoroethylenepropylene, perfluoroalkoxyethylene, polyester, polyethylene terephthalate, polyethylene naphthalate, polyimide, polyether imide, polyether, especially polyphenylene ether (PPE), polymethyl (meth)acrylate, cycloolefin polymers, cycloolefin copolymers, polyolefins, especially polypropylene, polystyrene and/or mixtures thereof. The mixtures can be homogeneous or phase-separated. The wide choice of materials according to the invention can advantageously also permit adaptation to particular applications.

In a further embodiment of the layer composite according to the invention, the tunnel-like voids in the polymer layer structure produced by extrusion are filled with gases which are selected from the group comprising nitrogen (N₂), dinitrogen monoxide (N₂O) and/or sulfur hexafluoride (SF₆). As a result of the filling with gas, markedly higher piezoelectric constants can advantageously be achieved in the polymer layer composites according to the invention by polarisation. In order to enclose the gas filling in the polymer layer structure, it will be understood that the tunnel-like voids are to be closed at the ends.

In a further embodiment of the polymer layer structure according to the invention, the polymer layer structure further comprises one or more electrodes. In particular, the polymer layer structure according to the invention can have a conducting coating on at least part of the outwardly oriented surfaces of the polymer films. These conducting regions can be used as electrodes. The conducting coating, that is to say the electrodes, can be applied extensively and/or in a structured manner. A structured conducting coating can be configured, for example, as an application in strips or in grid form. The sensitivity of the polymer layer composite can hereby additionally be influenced and adapted to particular applications.

The chosen electrode materials can be conductive materials known to the person skilled in the art. According to the invention there are suitable for that purpose, for example, metals, metal alloys, conductive oligomers or polymers, such as, for example, polythiophenes, polyanilines, polypyrroles, conductive oxides, such as, for example, mixed oxides such as ITO, or polymers filled with conductive fillers. Suitable fillers for polymers filled with conductive fillers are, for example, metals, conductive carbon-based materials, such as, for example, carbon black, carbon nanotubes (CNTs), or conductive oligomers or polymers. The filler content of the polymers is above the percolation threshold so that the conductive fillers form continuous electrically conductive paths.

The electrodes can be produced by processes known per se, for example by metallisation of the surfaces, by sputtering, vapour deposition, chemical vapour deposition (CVD), printing, doctor blade application, spin coating, adhesive bonding or printing of a conducting layer in prefabricated form or by an emission electrode of a conducting plastic. The electrodes can have a structured configuration, for example in strips or in grid form. For example, according to an embodiment of the invention the electrodes can also be so structured that the polymer layer structure as an electromechanical converter has active and passive regions. For example, the electrodes can be so structured that, in particular in a sensor mode, the signals can be detected in a space-resolved manner and/or, in particular in an actuator mode, the active regions can purposively be triggered. This can be achieved, for example, by providing the active regions with electrodes while the passive regions do not have electrodes.

According to a further advantageous embodiment of the invention, it is additionally provided that two or more polymer layer structures having a conducting layer, that is to say an electrode, of the same polarity can be connected. In other words, it is possible for an intermediate electrode to be formed between two polymer layer structures according to the invention, which intermediate electrode can be switched counter to the two electrodes on the then outer surfaces. The ferroelectret multilayer composites can thus be connected in series and the achievable piezoelectric effect can be doubled or multiplied.

The polymer layer structures according to the invention preferably contain two electrodes. Electromechanical converters having more than two electrodes can be, for example, stacked structures of a plurality of polymer layer structure systems preferably produced according to the invention.

The present invention relates further to a process for the production of a polymer layer composite according to the invention, comprising the steps:
(A) providing a polymer material,
(B) extruding the polymer material to form a polymer layer structure comprising a continuous first polymer layer and a continuous second polymer layer, the first and second polymer layers being connected to one another to form voids by connecting portions arranged between the continuous polymer layers, and
(C) electrically charging the surfaces of the first and second polymer layers that are facing the voids.

With regard to details and advantages of the process according to the invention, reference is made to the explanations given in respect of the polymer layer structure according to the invention.

According to an embodiment of the process according to the invention, the application of electrodes to the outer surfaces of the polymer layer structure can take place before and/or after the electrical charging of the inner surfaces of the voids in step (C). The application of electrodes to the outer surfaces is understood as meaning the provision of a conducting surface coating in at least a partial region, in particular on the outwardly oriented surfaces of the polymer layer composite.

In a further embodiment of the process according to the invention, the electrical charging in step (C) is carried out by means of direct charging or corona discharge. In particular, charging can be carried out by a two-electron corona arrangement. The stylus voltage can be ≧20 kV, ≧25 kV and in particular ≧30 kV. The charging time can be ≧20 seconds, ≧25 seconds and in particular ≧30 seconds.

“Direct charging” is to be understood as meaning charging when direct charging is carried out by application of an electric voltage after the application of electrodes to the outer surfaces of the polymer layer structure. Before the application of electrodes, polarisation of the opposing sides of the voids can be achieved by a corona discharge. A corona treatment can advantageously also be used successfully on a large scale. According to the invention it is also possible first to provide a conducting surface coating on a surface, then to charge the polymer layer structure and finally to apply a second electrode to the opposite outer surface.

In a further embodiment of the process according to the invention, before the electrical charging in step (C) the voids are filled with gases selected from the group comprising nitrogen, nitrogen monoxide and/or sulfur hexafluoride. As already described, it is advantageously possible by means of the introduction of gas to achieve markedly higher piezoelectric constants in the polymer layer composites according to the invention as a result of polarisation. It will be understood here that the voids extending in a tunnel-like manner through the polymer layer structure must be closed at their ends so that the gas that is introduced remains in the voids.

The present invention further provides a piezoelectric element comprising a polymer layer structure according to the invention. The piezoelectric element can particularly preferably be a sensor, actuator or generator element. The invention can advantageously be implemented in a large number of very different applications in the electromechanical and electroacoustic field, in particular in the field of obtaining energy from mechanical vibrations (energy harvesting), acoustics, ultrasound, medical diagnostics, acoustic microscopy, mechanical sensor systems, in particular pressure, force and/or strain sensor systems, robotics and/or communication technology.

Typical examples thereof are pressure sensors, electroacoustic converters, microphones, loudspeakers, vibration transducers, light deflectors, membranes, modulators for fibre optics, pyroelectric detectors, capacitors and control systems and “intelligent” flooring.

The present invention is explained further with reference to the following drawing, without being limited thereto.

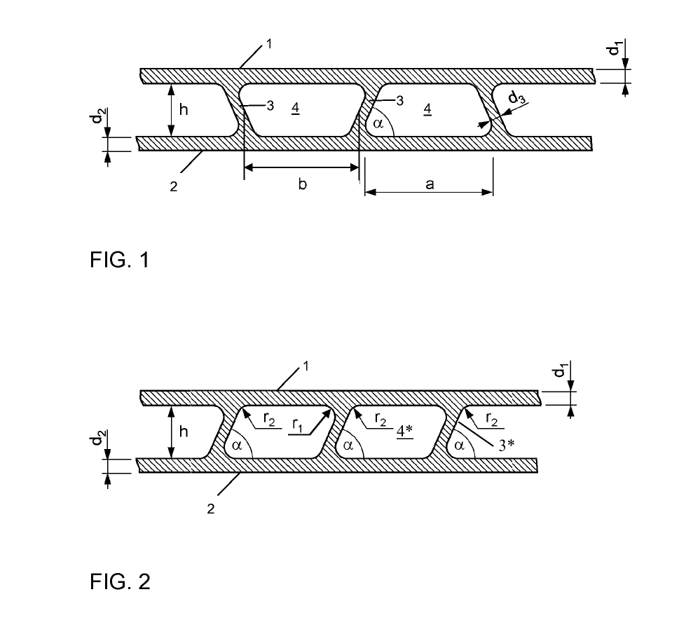

FIG. 1 shows a cross-sectional view of an extruded polymer layer structure having trapezoidal void cross-sections.

FIG. 2 shows a cross-sectional view of an alternative extruded polymer layer structure having parallelogram-shaped void cross-sections.

For the purpose of better understanding, in particular of the dimensioning, FIG. 1 shows a polymer layer structure with ferroelectret properties in cross-section. The polymer layer structure of FIG. 1 comprises a continuous first polymer layer 1, in the present case arranged on the top, and a continuous second polymer layer 2. The two polymer layers 1, 2 have a substantially constant thickness d1, d2, for example 50 μm. The two continuous polymer layers 1, 2 are connected to one another by connecting portions 3 which are arranged at an angle relative to the continuous polymer layers. The thickness d3 of the connecting portions 3 is preferably likewise 50 μm. Tunnel-like voids 4 are thereby formed—corresponding to the production process—the connecting portions 3 connecting the two polymer layers 1, 2 being so arranged at an acute angle relative to the polymer layers 1, 2 and to one another that the voids 4 each have a cross-section in the form of a symmetrical trapezium. The longer base of a trapezium cross-section is arranged alternately above and below the associated shorter base, so that adjacent trapezium cross-sections are oriented in a point-reflected manner relative to one another. The angle α enclosed between the longer base of each trapezium cross-section and the adjacent connecting portions can have values from 5 to 80°. In the present case, the angle is about 60°. Good structural softness and accordingly high suitability in particular as a sensitive sensor and as a generator (energy harvesting) are thereby achieved.

FIG. 2 shows a cross-sectional view of an alternative extruded polymer layer structure having parallelogram-shaped void cross-sections 4* as a special case of trapezoidal void cross-sections. The connecting portions 3* are here inclined “in the same direction” relative to the imaginary perpendicular connection of the parallel continuous polymer layers 1, 2. Consequently, the width a —which is not indicated explicitly in FIG. 2—also corresponds to the width b at half height. It will be understood that the thicknesses d1, d2 and the angle α can have the values mentioned above.

Not shown is an embodiment in which a plurality of the polymer layer structures shown in FIG. 1 are stacked one above the other to form a stack, continuous polymer layers that face one another of adjacent stacked polymer layer structures being charged with the same polarisation. Between the individual polymer layer structures there are arranged electrode layers which are in contact with the continuous polymer layers of the same polarisation.

1. A polymer layer structure with ferroelectret properties, comprising:
a continuous first polymer layer and
a continuous second polymer layer,
said first and second polymer layers being connected with one another to form voids by connecting portions arranged between said continuous polymer layers,
wherein
said polymer layer structure is in the form of an integral extruded structural element.

2. The polymer layer structure according to claim 1,
wherein
thicknesses d1 and d2 of said first and second polymer layers are constant.

3. The polymer layer structure according to claim 1,
wherein
at least one of the voids comprises a trapezoidal cross-section.

4. The polymer layer structure according to claim 3,
wherein
at least one of the voids comprises a symmetrical trapezoidal cross-section with trapezium legs of equal lengths.

5. The polymer layer structure according to claim 3,
wherein
all the voids comprise a trapezoidal cross-section, a longer base of a trapezium cross-section in a case of a horizontally arranged polymer layer structure being arranged alternately above and below an associated shorter base.

6. The polymer layer structure according to claim 3,
wherein
in the trapezoidal cross-section, each obtuse angle comprises two adjacent acute angles and each acute angle comprises two adjacent obtuse angles.

7. The polymer layer structure according to claim 6,
wherein
said trapezoidal cross-section is parallelogram-shaped.

8. The polymer layer structure according to claim 2,
wherein
the thickness d1 is from ≧10 μm to ≦250 μm,
the thickness d2 is from ≧10 μm to ≦250 μm,
a width a is from ≧10 μm to ≦5 mm,
a width b is from ≧10 μm to ≦5 mm,
a maximum height h is from ≧10 μm to ≦500 μm and/or
an angle α is from 5° to ≦80°.

9. The polymer layer structure according to claim 1,
wherein
said polymer layer structure comprises a material which is at least one selected from the group consisting of polycarbonate, perfluorinated or partially fluorinated polymers and copolymers, polytetrafluoroethylene, fluoroethylenepropylene, perfluoroalkoxyethylene, polyester, polyethylene terephthalate, polyethylene naphthalate, polyimide, polyether imide, polyether, polyphenylene ether (PPE), polymethyl (meth)acrylate, cycloolefin polymers, cycloolefin copolymers, polyolefins, polypropylene, and polystyrene.

10. The polymer layer structure according to claim 1,
wherein
the voids are filled with at least one gas selected from the group consisting of nitrogen, dinitrogen monoxide and sulfur hexafluoride.

11. The polymer layer structure according to claim 1,
wherein
said polymer layer structure comprises at least one electrode.

12. A process for producing a polymer layer structure,
comprising:
(A) providing a polymer material,
(B) extruding the polymer material to form a polymer layer structure comprising a continuous first polymer layer and a continuous second polymer layer, said first and second polymer layers being connected to one another to form voids by connecting portions arranged between said continuous polymer layers, and
(C) electrically charging surfaces of said first and second polymer layers, that are facing the voids.

13. Process according to claim 12,
wherein
said electrical charging in step (C) is carried out by direct charging and/or corona discharge.

14. Process according to claim 12,
wherein
before said electrical charging in (C), the voids are filled with at least one gas selected from the group consisting of nitrogen, nitrogen monoxide and sulfur hexafluoride.

15. Piezoelectric element comprising a polymer layer composite according to claim 1.

16. The polymer layer structure according to claim 2,
wherein
at least one of the voids comprises a trapezoidal cross-section.

17. The polymer layer structure according to claim 4,
wherein
all the voids comprise a trapezoidal cross-section, a longer base of a trapezium cross-section in the case of a horizontally arranged polymer layer structure being arranged alternately above and below an associated shorter base.

18. Process according to claim 13,
wherein
before said electrical charging in (C), the voids are filled with at least one gas selected from the group consisting of nitrogen, nitrogen monoxide and sulfur hexafluoride.
